(19) United States
(12) Patent Application Publication
(10) Pub. No.: US 2016/0189866 A1
(43) Pub. Date: Jun. 30, 2016

(54) METHOD FOR FORMING EXTERNAL ELECTRODE OF ELECTRONIC COMPONENT

(71) Applicant: MURATA MANUFACTURING CO., LTD., Kyoto-fu (JP)

(72) Inventors: Shunsuke KITAMURA, Nagaokakyo-shi (JP); Akio KATSUBE, Nagaokakyo-shi (JP)

(73) Assignee: MURATA MANUFACTURING CO., LTD., Kyoto-fu (JP)

(21) Appl. No.: 15/065,391

(22) Filed: Mar. 9, 2016

Related U.S. Application Data
(63) Continuation of application No. PCT/JP2014/071545, filed on Aug. 18, 2014.

(30) Foreign Application Priority Data
Sep. 11, 2013 (JP) 2013-187995

(51) Int. Cl. H01G 4/232; H01F 41/32; H03H 3/007; H01G 13/00

(52) U.S. Cl. CPC H01G 4/2325; H01G 13/006; H01F 41/32; H03H 3/007

(57) ABSTRACT

A method for forming an external electrode of an electronic component, which can apply sufficient conductive paste to even an end, and is able to enhance reliability as an electronic component. In the method for forming an external electrode of an electronic component, a conductive paste is applied to a printing target through a metal mask composed of a hole and a mesh portion disposed to surround the outer perimeter of the hole. The metal mask has the outer perimeter of the hole located inside a printing region of the printing target, and the outer perimeter of the mesh portion is located outside the printing region of the printing target.

### CROSS REFERENCE TO RELATED APPLICATIONS

This application claims benefit of priority to Japanese Patent Application 2013-187995 filed Sep. 11, 2013, and to International Patent Application No. PCT/JP2014/071545 filed Aug. 18, 2014, the entire content of which is incorporated herein by reference.

### TECHNICAL FIELD

The present disclosure relates to a method for forming an external electrode of an electronic component, which can reliably cover even an end with a conductive paste.

### BACKGROUND

Conventionally, in the case of forming external electrodes in the process of manufacturing electronic components with the use of a plurality of laminated chips composed of laminated bodies of a plurality of ceramic layers and a plurality of internal electrode layers, a conductive paste is applied with the use of a screen mask so as to cover the surfaces where the internal electrode layers are exposed.

Japanese Patent Application Laid-Open No. 07-201686 discloses a method for forming an end surface electrode of a surface-mounted electronic component, wherein an electrode material paste (conductive paste) is embedded in a mesh portion and an emulsion part of an opening of a screen mask is used to print, after scraping off the excessive conductive paste, with the use of a stage for end surface electrodes.

### SUMMARY

### Problem to be Solved by the Disclosure

The conventional method for forming an end surface electrode as disclosed in Japanese Patent Application Laid-Open No. 07-201686 has the problem of easily producing asperity at the surface of an end surface electrode without sufficiently leveling the conductive paste, due to the generation of a mesh mark on the end surface electrode or the generation of a void in the interwoven part of the mesh.

In addition, when a laminated chip on which an external electrode is to be formed is large in size, the application of a conductive paste by a roller transfer or the like as in conventional cases has the possibility of exposing the base without sufficiently applying the conductive paste to ends. Therefore, there has been a possibility of moisture ingress from the ends of the laminated chip (printing target), and there has been a problem of making it difficult to enhance reliability as an electronic component.

The present disclosure has been made in view of such circumstances, and an object of the present disclosure is to provide a method for forming an external electrode of an electronic component, which can apply a sufficient conductive paste to even an end, and is able to enhance reliability as an electronic component.

### Solving the Problem

In order to achieve the object mentioned above, the method for forming an external electrode of an electronic component according to the present disclosure is a method for forming an external electrode of an electronic component, wherein a conductive paste is applied to a printing target through a metal mask composed of a hole and a mesh portion disposed to surround the outer perimeter of the hole, and the metal mask has the outer perimeter of the hole located inside a printing region of the printing target, and the outer perimeter of the mesh portion is located outside the printing region of the printing target.

In the configuration mentioned above, the conductive paste is applied to the printing target through the metal mask composed of the hole and the mesh portion is disposed to surround the outer perimeter of the hole. The metal mask has the outer perimeter of the hole located inside the printing region of the printing target, and the outer perimeter of the mesh portion is located outside the printing region of the printing target. Thus, the conductive paste passing through the mesh portion can be applied to an end of the printing target to form an external electrode which is smaller in film thickness than that on a central part with the applied conductive paste passing through the hole. Therefore, the film thickness can be made uniform on a central part of the printing target (for example, an external electrode surface), and by appropriately setting the size and opening ratio of the mesh portion, the conductive paste can be applied to cover the base reliably without dropping down at ends of the printing target. Thus, moisture ingress from ends of the printing target can be prevented, and it becomes possible to manufacture a highly reliable electronic component.

In addition, in the method for forming an external electrode of an electronic component according to the present disclosure, the mesh portion of the metal mask preferably has an opening ratio of 16% or more and 36% or less.

In the configuration mentioned above, since the mesh portion of the metal mask has an opening ratio of 16% or more and 36% or less, the conductive paste can also be applied sufficiently to ends of the printing target, and the conductive paste does not excessively adhere to the ends of the printing target.

In addition, in the method for forming an external electrode of an electronic component according to the present disclosure, each opening has a circular shape in the mesh portion of the metal mask.

In the configuration mentioned above, each opening has a circular shape in the mesh portion of the metal mask. Thus, the conductive paste passing through the mesh portion can be applied to a peripheral edge of the printing target to form an external electrode which is smaller in film thickness than that on a central part with the applied conductive paste passing through the hole. Therefore, the film thickness can be made uniform on a central part of the printing target (for example, an external electrode surface), and by appropriately setting the size and opening ratio of the mesh portion, the conductive paste can be applied to cover the base reliably without dropping down at a peripheral edge of the printing target. Thus, moisture ingress from a peripheral edge of the printing target can be prevented, and it becomes possible to manufacture a highly reliable electronic component.

In addition, in the method for forming an external electrode of an electronic component according to the present disclosure, the metal mask preferably differs in the thickness of the mesh portion between a part in contact with the printing target and the other part.

In the configuration mentioned above, for example, by making the thickness of the part of the mesh portion coming into contact with the printing target smaller than that of the other part, printing can be carried out while positioning the metal mask. Therefore, the conductive paste can be applied in a more precise location, and by appropriately setting the size and opening ratio of the mesh portion, the conductive paste can be applied to cover the base reliably without dropping down at an end (peripheral edge) of the printing target. In addition, since the amount of the conductive paste applied can be further reduced at an end (peripheral edge) of the printing target, the film thickness at an end (peripheral edge) of the printing target can be further reduced. Thus, moisture ingress from ends (peripheral edge) of the printing target can be prevented, and it becomes possible to manufacture a highly reliable electronic component.

### Advantageous Effect of the Disclosure

In the configuration mentioned above, the metal mask has the outer perimeter of the hole located inside the printing region of the printing target, and the outer perimeter of the mesh portion located outside the printing region of the printing target. Thus, the conductive paste passing through the mesh portion can be applied to an end of the printing target to form an external electrode which is smaller in film thickness than that on a central part with the applied conductive paste passing through the hole. Therefore, the film thickness can be made uniform on a central part of the printing target (for example, an external electrode surface), and by appropriately setting the size and opening ratio of the mesh portion, the conductive paste can be applied to cover the base reliably without dropping down at ends of the printing target. Thus, moisture ingress from ends of the printing target can be prevented, and it becomes possible to manufacture a highly reliable electronic component.

### BRIEF DESCRIPTION OF THE DRAWINGS

FIGS. 1(a) and 1(b) are schematic diagrams illustrating the configuration of a metal mask for use in a method for forming an external electrode of an electronic component according to an embodiment of the present disclosure.

FIGS. 2(a) to 2(f) are schematic diagrams illustrating differences of applied conductive pastes, due to differences in the opening ratio of a mesh portion of a metal mask for use in a method for forming an external electrode according to an embodiment of the present disclosure.

FIG. 3 is a pattern diagram of a device for manufacturing an electronic component for embodying a method for forming an external electrode of an electronic component according to an embodiment of the present disclosure.

FIGS. 4(a) and 4(b) are pattern diagrams for explaining a printing state in a mesh portion in a method for forming an external electrode of an electronic component according to an embodiment of the present disclosure.

FIGS. 5(a) and 5(b) are pattern diagrams illustrating steps of manufacturing an electronic component for embodying a method for forming an external electrode of an electronic component according to an embodiment of the present disclosure.

FIGS. 6(a) and 6(b) are pattern diagrams illustrating dimensions of the outer perimeter of a mesh portion in a method for forming an external electrode of an electronic component according to an embodiment of the present disclosure.

FIGS. 7(a) to 7(d) are plan views illustrating a conductive paste applied in a method for forming an external electrode of an electronic component according to an embodiment of the present disclosure.

FIG. 8 is a pattern diagram of a device for manufacturing an electronic component for embodying a method for forming an external electrode of an electronic component according to an embodiment of the present disclosure.

### DETAILED DESCRIPTION

An embodiment of the present disclosure will be described in detail below with reference to the drawings. It is to be noted that a case of carrying out on-contact printing with a metal mask brought into contact with a printing target for the formation of an external electrode will be described in the present embodiment. However, the disclosure can also be applied to off-contact printing without any metal mask brought into contact.

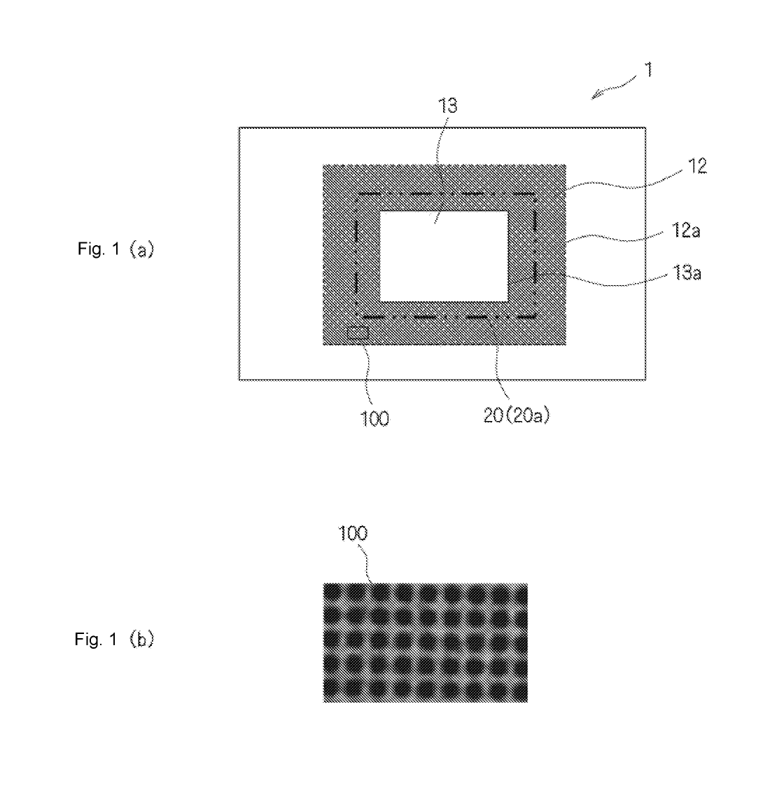

FIGS. 1(a) and 1(b) are schematic diagrams illustrating the configuration of a metal mask for use in a method for forming an external electrode of an electronic component according to an embodiment of the present disclosure. FIG. 1(a) and FIG. 1(b) respectively illustrate a plan view of a metal mask 1 according to the present embodiment, and a partial enlarged view of a region 100 in FIG. 1(a). It is to be noted that electronic components that are manufactured by a method for forming an external electrode of an electronic component according to the present embodiment include, for example, multilayer ceramic capacitors, multilayer ceramic inductors, multilayer ceramic components, surface wave filters, and ceramic oscillators.

First, as illustrated in FIG. 1(a), the metal mask 1 is prepared which is provided with a hole 13 in accordance with the size of a printing target. The size of the hole 13 is specifically determined depending on the width dimension and height dimension of an electronic component manufactured.

The metal mask 1 according to the present embodiment is composed of the hole 13, and a mesh portion 12 disposed to surround the outer perimeter 13a of the hole 13. Specifically, the outer perimeter 13a of the hole 13 is located inside a printing region 20a of a printing target 20, and the outer perimeter 12a of the mesh portion 12 is located outside the printing region 20a of the printing target 20. The printing region 20a of the printing target 20 in the present embodiment refers to, for example, an end surface of an electronic component, which is the region indicated by a chain double-dashed line in FIGS. 1(a) and 1(b).

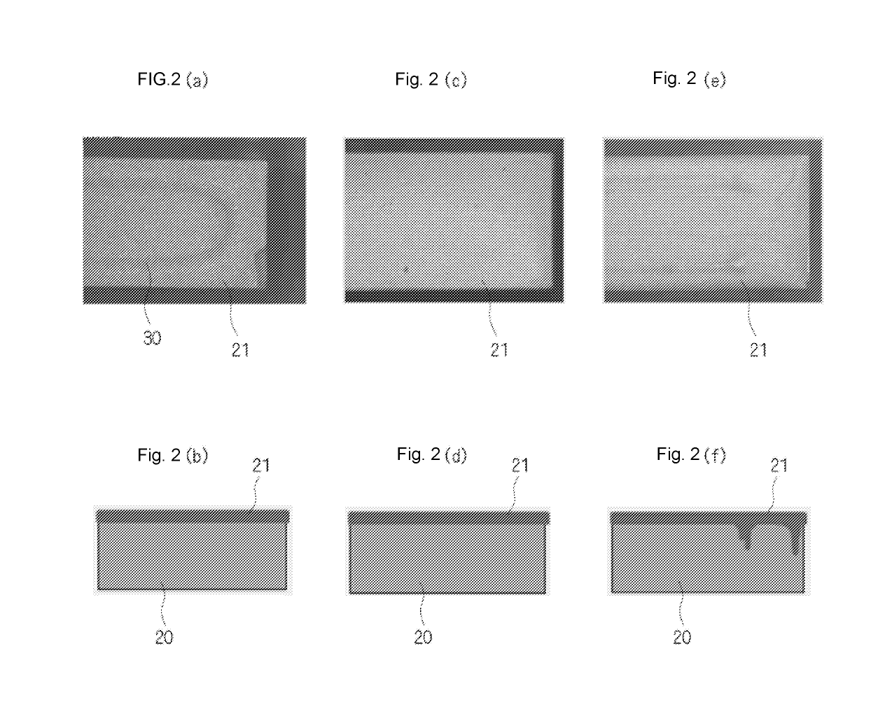

In addition, as illustrated in FIG. 1(b), the mesh portion 12 of the metal mask 1 is composed of, for example, a plurality of circular through holes. The mesh portion 12 of the metal mask 1 preferably has an opening ratio of 16% or more and 36% or less. FIGS. 2(a) to 2(f) are schematic diagrams illustrating differences of applied conductive pastes 21, due to differences in the opening ratio of the mesh portion 12 of the metal mask 1 for use in a method for forming an external electrode according to an embodiment of the present disclosure.

FIG. 2(a) and FIG. 2(b) respectively illustrate a plan view illustrating the conductive paste 21 applied when the opening ratio of the mesh portion 12 is less than 16%, and a side view illustrating the conductive paste 21 applied when the opening ratio of the mesh portion 12 is less than 16%. FIG. 2(c) and FIG. 2(d) respectively illustrate a plan view illustrating the conductive paste 21 applied when the opening ratio of the mesh portion 12 is 16% or more and 36% or less, and a side view illustrating the conductive paste 21 applied when the opening ratio of the mesh portion 12 is 16% or more and 36% or less. FIG. 2(e) and FIG. 2(f) respectively illustrate a plan view illustrating the conductive paste 21 applied when the opening ratio of the mesh portion 12 is 37% or more, and a side view illustrating the conductive paste 21 applied when the opening ratio of the mesh portion 12 is 37% or more.

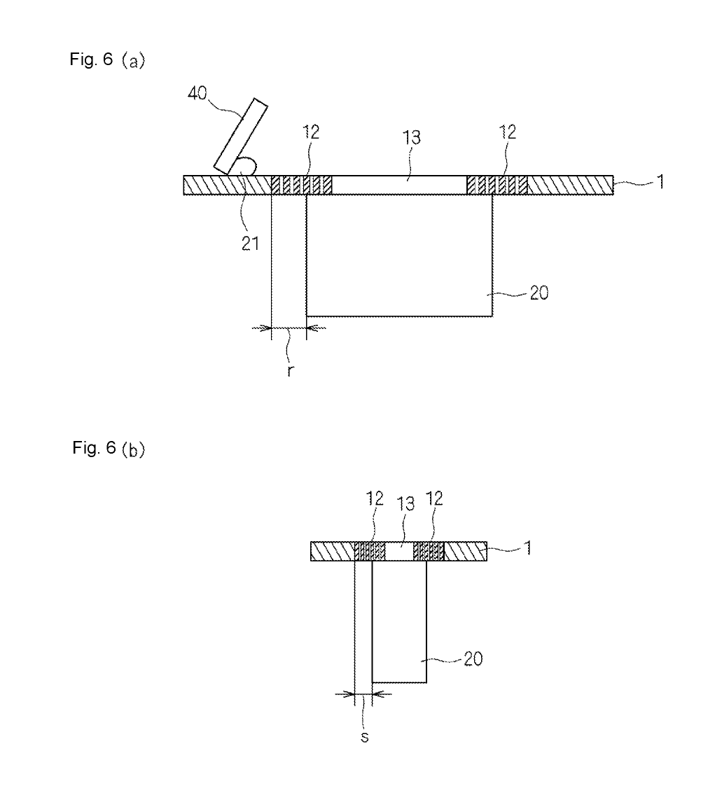

As illustrated in FIG. 2(a), when the opening ratio is less than 16%, there is a surface asperity increase, such as the conductive paste 21 applied to the printing region 20a with a large depressed part 30 produced, and there is a possibility that the conductive paste 21 cannot be applied sufficiently so as to cover an end of the printing target 20. As illustrated in FIG. 2(f), when the opening ratio is more than 36%, the conductive paste 21 excessively adheres to an end of the printing target 20, and there is thus a possibility that the conductive paste 21 drops onto a side surface. Accordingly, as illustrated in FIGS. 6(c) and 6(d), the opening ratio of the mesh portion 12 is preferably 16% or more and 36% or less.

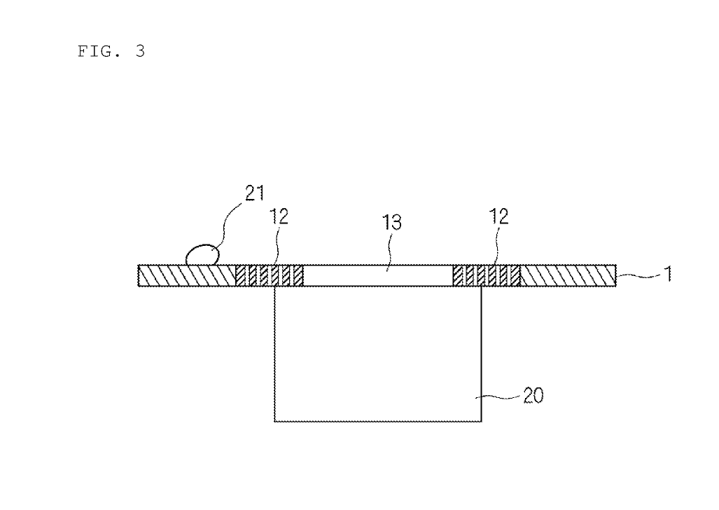

FIG. 3 is a pattern diagram of a device for manufacturing an electronic component for embodying a method for forming an external electrode of an electronic component according to an embodiment of the present disclosure. As illustrated in FIG. 3, the metal mask 1 illustrated in FIGS. 1(a) and 1(b) is brought into contact with the printing target 20. The mesh portion 12 of the metal mask 1 has a part close to the hole 13 and coming into contact with the printing target 20, and the other part not coming into contact therewith.

In this state, the conductive paste 21 is applied to the metal mask 1 from the side opposite to the side being in contact with the printing target 20. Then, the applied conductive paste 21 is applied to the printing target 20.

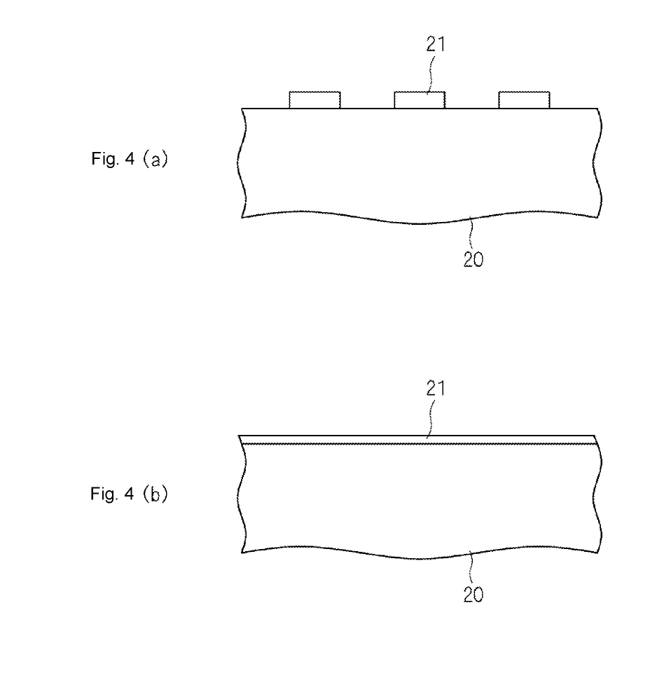

FIGS. 4(a) and 4(b) are pattern diagrams for explaining a printing state in the mesh portion 12 in a method for forming an external electrode of an electronic component according to an embodiment of the present disclosure. The conductive paste 21 passing through the mesh portion 12 is applied so as to be dotted on the surface of the printing target 20, as illustrated in FIG. 4(a). When this state is left for a while, the uncured conductive paste 21 is leveled, and spreads to achieve uniformity in film thickness as illustrated in FIG. 4(b). Since the amount of the conductive paste 21 passing through the mesh portion 12 is smaller than the amount of the conductive paste 21 passing through the hole 13, the film thickness after the leveling is such that the film thickness of the part being in contact with the mesh portion 12 becomes smaller than the film thickness of the part being in contact with the hole 13.

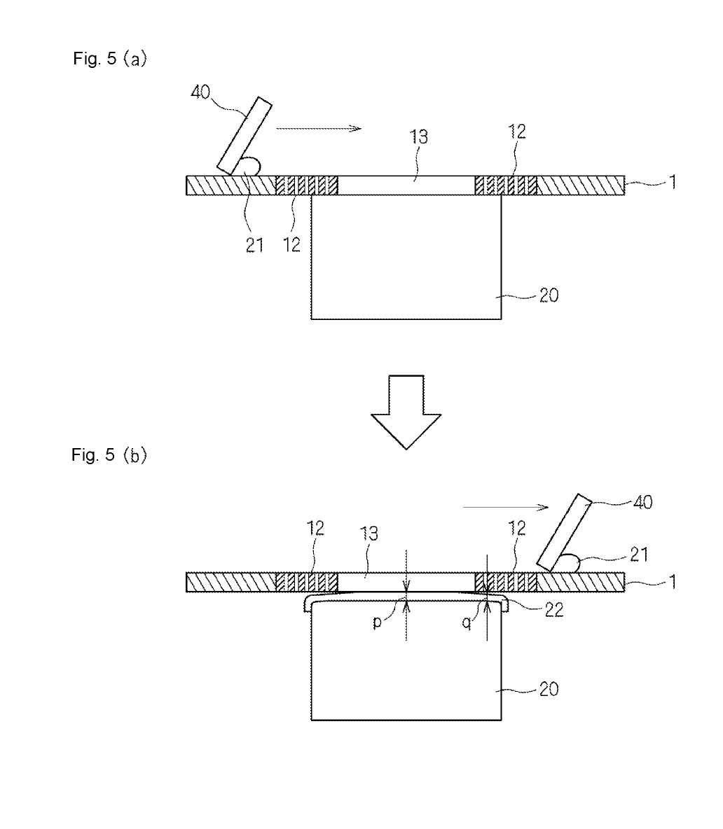

FIGS. 5(a) and 5(b) are pattern diagrams illustrating steps of manufacturing an electronic component for embodying a method for forming an external electrode of an electronic component according to an embodiment of the present disclosure. FIG. 5(a) and FIG. 5(b) respectively illustrate a state before moving a squeegee 40 for applying the conductive paste 21, and a state after moving the squeegee 40 for applying the conductive paste 21.

In FIG. 5(a), as in FIG. 3, the metal mask 1 illustrated in FIGS. 1(a) and 1(b) is brought into contact with the printing target 20. Then, the conductive paste 21 is applied to the mesh portion 12 and the hole 13 by moving the squeegee 40 with a head made of urethane rubber in a direction of the arrow in the figure from the side opposite to the side being in contact with the printing target 20 of the metal mask 1.

The head shape of the squeegee 40 is not particularly limited. The head may have the shape of, for example, a sword, a horn, or a cuboid. In addition, the shape may have a corner chamfered in the direction of moving.

The conductive paste 21 is applied to the mesh portion 12 and the hole 13 by moving the squeegee 40 in the direction of the arrow in FIG. 5(a). Then, the applied conductive paste 21 is applied to the printing target 20. Through the application, as illustrated in FIG. 5(b), the conductive paste 21 passing through the mesh portion 12 and the hole 13 is leveled to reach a thin film state, and subjected to drying and firing to form an external electrode 22.

In FIG. 5(b), as for the external electrode 22, the thickness q of an end formed from the conductive paste 21 passing through the mesh portion 12 is smaller than the thickness p of a central part formed from the conductive paste 21 passing through the hole 13. This is because the amount of the conductive paste 21 passing through the mesh portion 12 is smaller than that of the conductive paste 21 passing through the hole 13. In addition, since the mesh portion 12 of the metal mask 1 has an opening ratio of 16% or more and 36% or less, the conductive paste 21 can be applied to cover the base reliably without dropping down at ends of the printing target 20.

Since by drying and firing with an oven or the like in this state, the external electrode 22 is formed, moisture ingress from ends of the printing target 20 can be prevented, and it becomes possible to manufacture a highly reliable electronic component.

Through the adoption of this configuration, the thickness of the conductive paste 21 applied to a peripheral edge of the printing target 20 by passage through the mesh portion 12 can be made smaller than the thickness of the conductive paste 21 applied by passage through the hole 13. Therefore, the film thickness can be made uniform on a central part of the printing target (for example, an external electrode) 20, and by appropriately setting the size and opening ratio of the mesh portion 12, the conductive paste 21 can be applied to cover the base reliably without dropping down at a peripheral edge. Thus, moisture ingress from a peripheral edge of the printing target 20 can be prevented, and it becomes possible to manufacture a highly reliable electronic component.

It is to be noted that the opening of the mesh portion 12 of the metal mask 1 preferably has a circular shape. Then, the outer perimeter of the mesh portion 12 of the metal mask 1 desirably has a dimension that is 0.6 mm or more larger on each longer side and a dimension that is 0.1 mm or more larger on each shorter side with respect to the standardized dimensions of the printing target 20. FIGS. 6(a) and 6(b) are pattern diagrams illustrating dimensions of the outer perimeter of the mesh portion 12 in a method for forming an external electrode of an electronic component according to an embodiment of the present disclosure. FIG. 6(a) and FIG. 6(b) respectively illustrate a pattern diagram as viewed from the longer side of the printing target 20 and a pattern diagram as viewed from the shorter side of the printing target 20.

As illustrated in FIG. 6(a), the outer perimeter of the mesh portion 12 of the metal mask 1 is formed to have a dimension increased by a length r on the longer side with respect to the standardized dimension of the printing target 20. The length r is preferably 0.6 mm or more. Likewise, as illustrated in FIG. 6(b), the outer perimeter of the mesh portion 12 of the metal mask 1 is formed to have a dimension increased by a length s on the shorter side with respect to the standardized dimension of the printing target 20. The length s is preferably 0.1 mm or more.

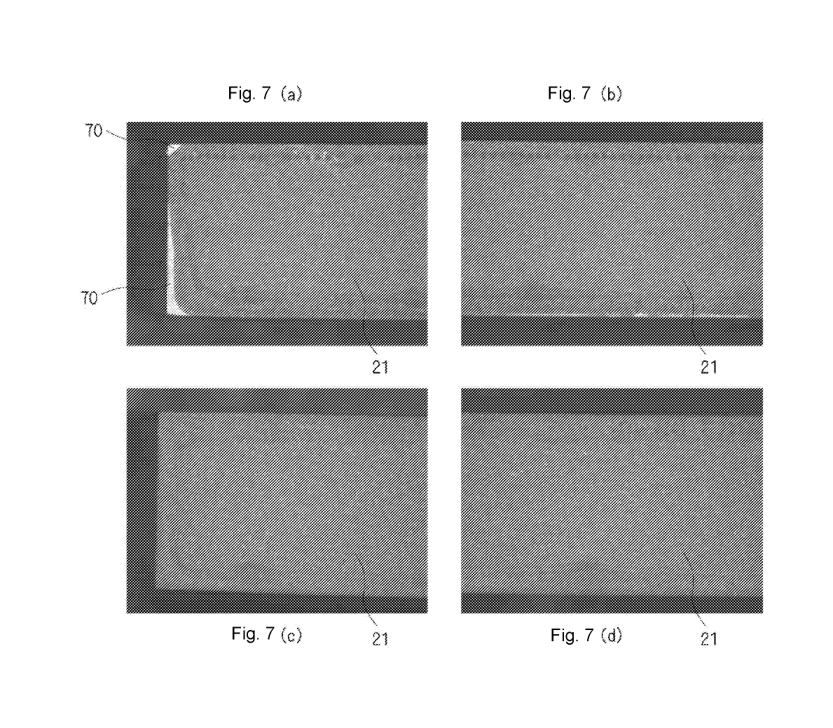

FIGS. 7(a) to 7(d) are plan views illustrating the conductive paste 21 applied in a method for forming an external electrode of an electronic component according to an embodiment of the present disclosure. FIGS. 7(a) and 7(b) and FIGS. 7(c) and 7(d) respectively illustrate the conductive paste 21 applied when the outer perimeter of the mesh portion 12 of the metal mask 1 has a dimension smaller than 0.6 mm on the longer side and a dimension smaller than 0.1 mm on the shorter side with respect to the standardized dimensions of the printing target 20, and the conductive paste 21 applied when the outer perimeter of the mesh portion 12 of the metal mask 1 has a dimension of 0.6 mm or more on the longer side and a dimension of 0.1 mm or more on the shorter side with respect to the standardized dimensions of the printing target 20.

As is also clear from FIGS. 7(a) to 7(d), the conductive paste 21 has succeeded in being applied evenly in FIGS. 7(c) and 7(d), whereas uncoated regions 70 without the conductive paste 21 applied to the printing surface account for approximately 10%, when the outer perimeter of the mesh portion 12 of the metal mask 1 has small dimensions as in FIGS. 7(a) and 7(b).

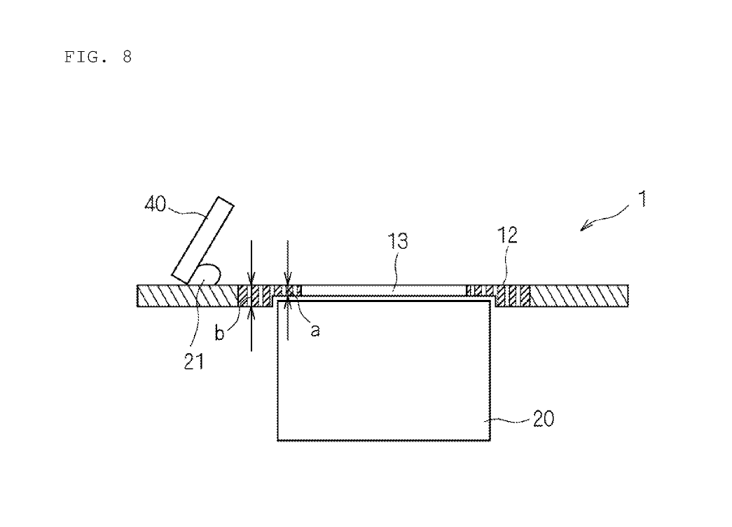

It is to be noted that the metal mask 1 may be used which differs in the thickness of the mesh portion 12 between the part in contact with the printing target 20 and the other part. FIG. 8 is a pattern diagram of a device for manufacturing an electronic component for embodying a method for forming an external electrode of an electronic component according to an embodiment of the present disclosure. As illustrated in FIG. 8, as for the mesh portion 12, the thickness “a” of the part in contact with the printing target 20 is smaller than the thickness “b” of the other part.

By making the thickness “a” of the part of the mesh portion 12 coming into contact with the printing target 20 smaller than the thickness “b” of the other part of the mesh portion 12, the metal mask 1 can be brought into contact with the printing target 20 while aligning the metal mask 1. Therefore, the conductive paste 21 can be applied in a more precise location, and by appropriately setting the size and opening ratio of the mesh portion 12, the conductive paste 21 can be applied to cover the base reliably without dropping down at an end (peripheral edge) of the printing target 20. In addition, since the amount of the conductive paste 21 applied can be further reduced at an end (peripheral edge) of the printing target 20, the film thickness at an end (peripheral edge) of the printing target 20 can be further reduced.

As described above, in the method for forming an external electrode of an electronic component according to the embodiment of the present disclosure, the metal mask 1 has the outer perimeter of the hole 13 located inside the printing region of the printing target 20, and the outer perimeter of the mesh portion 12 located outside the printing region of the printing target 20. Thus, the conductive paste 21 passing through the mesh portion 12 can be applied to an end (peripheral edge) of the printing target 20 to form the external electrode 22 which is smaller in film thickness than that on a central part with the applied conductive paste 21 passing through the hole 13. Therefore, the film thickness can be made uniform on a central part of the printing target (for example, external electrode surface) 20, and by appropriately setting the size and opening ratio of the mesh portion 12, the conductive paste 21 can be applied to cover the base reliably without dropping down at an edge (peripheral edge) of the printing target 20. Thus, moisture ingress from ends (peripheral edge) of the printing target 20 can be prevented, and it becomes possible to manufacture a highly reliable electronic component.

Besides, as a matter of course, the embodiment described above can be modified without departing from the scope of the present disclosure.

1. A method for forming an external electrode of an electronic component, said method comprising the steps of
applying a conductive paste to a printing target through a metal mask including a hole and a mesh portion disposed to surround an outer perimeter of the hole, and
the metal mask has the outer perimeter of the hole located inside a printing region of the printing target, and an outer perimeter of the mesh portion being located outside the printing region of the printing target.

2. The method for forming an external electrode of an electronic component according to claim 1, wherein the mesh portion of the metal mask has an opening ratio of 16% or more and 36% or less.

3. The method for forming an external electrode of an electronic component according to claim 1, wherein each opening has a circular shape in the mesh portion of the metal mask.

4. The method for forming an external electrode of an electronic component according to claim 1, wherein the metal mask differs in the thickness of the mesh portion between a part in contact with the printing target and another part.
